(19) United States
(12) Patent Application Publication
(10) Pub. No.: US 2019/0159362 A1
(43) Pub. Date: May 23, 2019

(54) TRANSMISSION DEVICE AND ELECTRONIC APPARATUS

(71) Applicant: FUJITSU LIMITED, Kawasaki-shi (JP)

(72) Inventors: Hiroyuki ABE, Kawasaki (JP); Koji SASAKI, Kawasaki (JP); Masatoshi YONEKURA, Kawasaki (JP); Koji IWAMOTO, Yokohama (JP); Katsunori SUZUKI, Kawasaki (JP)

(73) Assignee: FUJITSU LIMITED, Kawasaki-shi (JP)

(21) Appl. No.: 16/180,888

(22) Filed: Nov. 5, 2018

(30) Foreign Application Priority Data
Nov. 17, 2017 (JP) 2017-221770

(51) Int. Cl. H05K 7/20; H05K 7/14; H01H 21/86; H01R 12/70; H01R 12/72

(52) U.S. Cl. CPC H05K 7/20172; H05K 7/1431; H05K 7/20145; H01H 21/30; H01R 12/7082; H01R 12/722; H05K 7/1438; H01H 21/86

(57) ABSTRACT

A transmission device includes a housing, and a plurality of plug-in assemblies mounted in the housing, wherein each of the plug-in assembly that executes signal transmission and includes a board, heat generating parts mounted over the board and a fan that cools the heat generating parts.

### CROSS-REFERENCE TO RELATED APPLICATION

This application is based upon and claims the benefit of priority of the prior Japanese Patent Application No. 2017-221770, filed on Nov. 17, 2017, the entire contents of which are incorporated herein by reference.

### FIELD

The embodiments discussed herein are related to a transmission device and an electronic apparatus.

### BACKGROUND

A transmission device is capable of mounting a plurality of plug-in units or the like that executes processing relating to signal transmission. There is a configuration in which a card lever is installed in a communication plug-in unit. There is another configuration in which a card lever for inserting and removing a tray is installed in a tray unit installed inside an electronic apparatus. There is further configuration in which, when a card puller for inserting and removing an electronic circuit is pushed in, a pair of spring contacts and a facing copper foil pad are conducted to configure a switching circuit.

However, in the above-described techniques, since a space of a housing in which a plug-in unit is mounted is limited, it is difficult to add a cooling device such as a fan to the housing. Accordingly, there is a problem that cooling efficiency of the plug-in unit may not be improved.

The followings are reference documents.
[Document 1] Japanese Laid-open Patent Publication No. 2009-76944,
[Document 2] Japanese Laid-open Patent Publication No. 2010-87004, and
[Document 3] Japanese Laid-open Patent Publication No. 11-297413.

### SUMMARY

According to an aspect of the embodiments, a transmission device includes a housing, and a plurality of plug-in assemblies mounted in the housing, wherein each of the plug-in assembly that executes signal transmission and includes a board, heat generating parts mounted over the board and a fan that cools the heat generating parts.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating an example of a plug-in unit of a transmission device according to Embodiment 1;

FIG. 2 is a top view illustrating an example of the plug-in unit of the transmission device according to Embodiment 1;

FIG. 3 is a top view illustrating another example of the plug-in unit of the transmission device according to Embodiment 1;

FIG. 4 is a perspective view illustrating an example of a plug-in unit of a transmission device according to Embodiment 2;

FIG. 5 is a top view illustrating the example of the plug-in unit of the transmission device according to Embodiment 2;

FIG. 6 is a perspective view illustrating an example of a fan according to Embodiment 3;

FIG. 7 is a perspective view illustrating an example of a front surface of a card lever according to Embodiment 3;

FIG. 8 is a perspective view illustrating an example of a front surface in a state where the fan is attached to the card lever according to Embodiment 3;

FIG. 9 is a perspective view illustrating an example of a rear surface of the card lever according to Embodiment 3;

FIG. 10 is a perspective view illustrating an example of a rear surface in a state where the fan is attached to the card lever according to Embodiment 3;

FIG. 11 is a perspective view illustrating an example of a power supply connector according to Embodiment 3;

FIG. 12 is a diagram illustrating an example of a situation of a front surface when the card lever according to Embodiment 3 is opened;

FIG. 13 is a diagram illustrating an example of a situation of a rear surface when the card lever according to Embodiment 3 is opened; and

FIG. 14 is a perspective view illustrating an example of a shelf-type transmission device capable of storing the plug-in unit according to each embodiment.

### DESCRIPTION OF EMBODIMENTS

Hereinafter, embodiments of a transmission device and an electronic apparatus according to the present disclosure will be described in detail below with reference to the drawings.

### Embodiment 1

Plug-In Unit of Transmission Device According to Embodiment 1

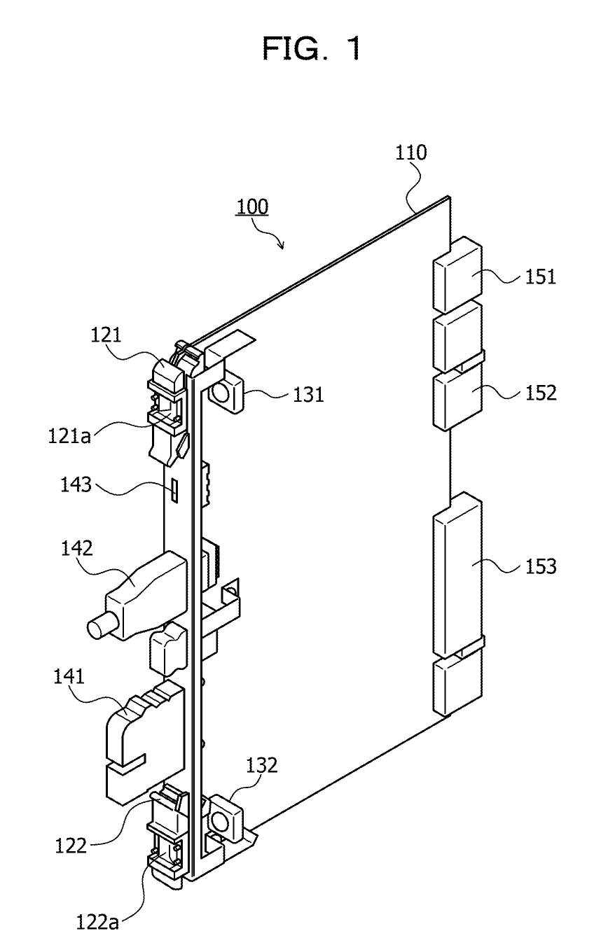

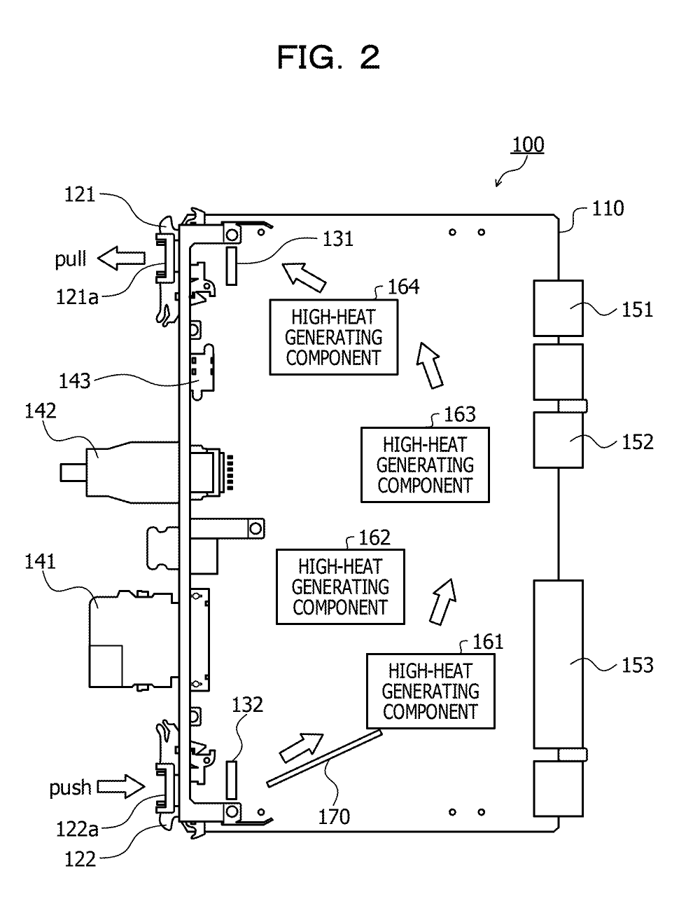

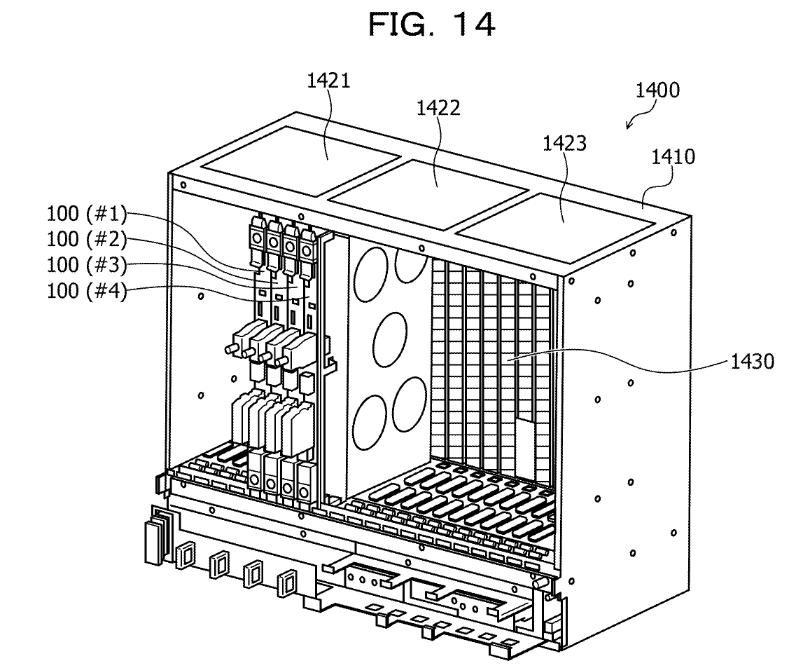

FIG. 1 is a perspective view illustrating an example of a plug-in unit of a transmission device according to Embodiment 1. FIG. 2 is a top view illustrating an example of the plug-in unit of the transmission device according to Embodiment 1. A plug-in unit 100 according to Embodiment 1 illustrated in FIGS. 1 and 2 is a packaged card-type processing device mounted as a plug-in in a housing of, for example, a shelf-type transmission device or the like. For example, the plug-in unit 100 is a processing device that executes processing relating to signal transmission. The shelf-type transmission device will be described below (see, for example, FIG. 14). The plug-in unit may be referred to as a plug-in card, a plug-in module, an expansion unit, an expansion card, an expansion module, or the like.

The plug-in unit 100 includes a board 110, card levers 121 and 122, fans 131 and 132, a power supply connector 141, a communication connector 142, a light emitting unit 143, back board connectors 151 to 153, and high-heat generating components 161 to 164. The plug-in unit 100 may include a rectifying plate 170. The high-heat generating components 161 to 164 and the rectifying plate 170 are not illustrated in FIG. 1.

The board 110 is a board on which a circuit that realizes a function of the plug-in unit 100 is mounted. For example, the high-heat generating components 161 to 164 which will be described below are mounted on the board 110. The function of the plug-in unit 100 includes, for example, processing relating to signal transmission.

The card levers 121 and 122 are operation tools that receive an operation for taking out the plug-in unit 100 from the shelf-type transmission device. The card levers 121 and 122 are each installed at both ends, in a longitudinal direction (up and down direction in FIG. 2), of a front surface (a left side in FIG. 2) of the plug-in unit 100. The card levers 121 and 122 are formed of a resin or the like.

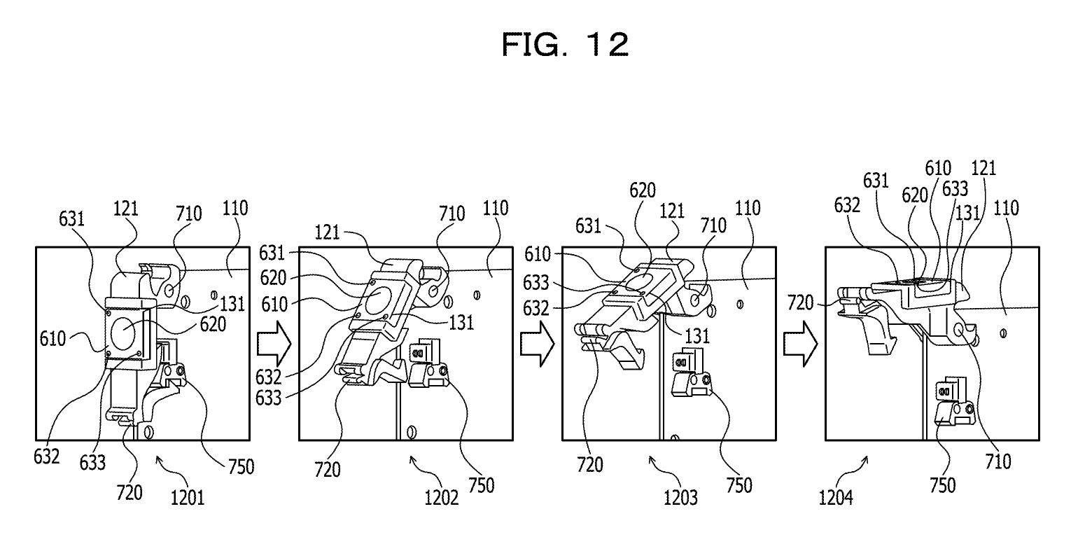

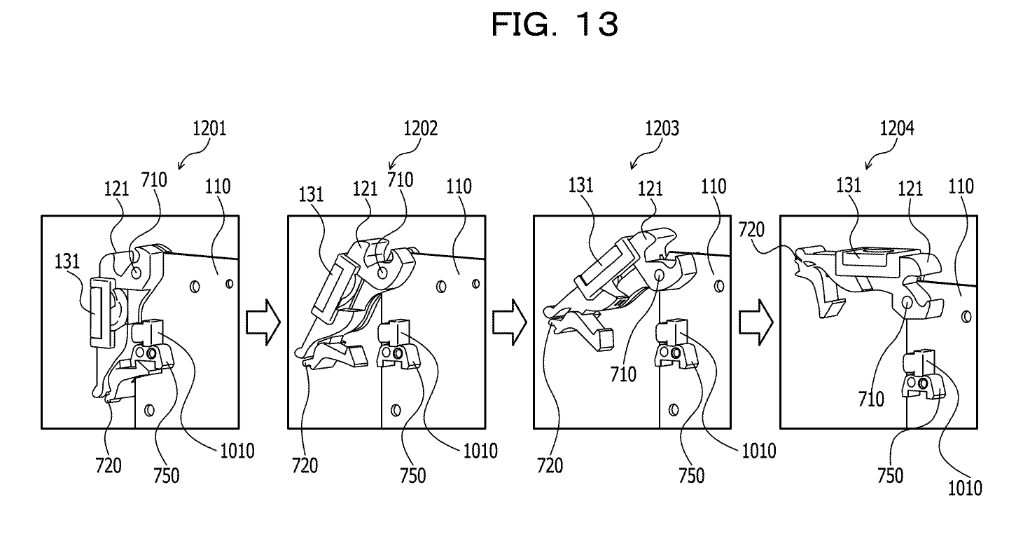

In a case where the plug-in unit 100 is stored in the shelf-type transmission device, a user pulls out the plug-in unit 100 after performing an operation to open the card levers 121 and 122, thereby, being able to take out the plug-in unit 100 from the shelf-type transmission device. The user may fix the plug-in unit 100 to the shelf-type transmission device by performing an operation to insert the plug-in unit 100 into the shelf-type transmission device and then close the card levers 121 and 122. Operations of the card levers 121 and 122 will be described below (see, for example, FIGS. 12 and 13).

The card levers 121 and 122 include openings 121a and 122a, respectively. The opening 121a is a hole (cavity) that penetrates the card lever 121 from the outside of the plug-in unit 100 to the inside of the plug-in unit 100 in a front surface of the plug-in unit 100. The opening 122a is a hole that penetrates the card lever 122 from the outside of the plug-in unit 100 to the inside of the plug-in unit 100 in the front surface of the plug-in unit 100.

The fans 131 and 132 are blowers that are installed on the board 110 and that are operated by electric power supplied from the board 110. In the example illustrated in FIGS. 1 and 2, the fan 131 is installed in the vicinity of the opening 121a of the card lever 121 on the board 110, and moves air from the inside of the plug-in unit 100 to the opening 121a. Thereby, the air inside the plug-in unit 100 is discharged to the outside of the plug-in unit 100 through the opening 121a (pull). The fan 132 is installed in the vicinity of the opening 122a of the card lever 122 on the board 110, and moves air from the opening 122a to the inside of the plug-in unit 100. Thereby, the air outside the plug-in unit 100 is pushed into the inside of the plug-in unit 100 through the opening 122a (push).

The fans 131 and 132 discharge (pull) the air of the plug-in unit 100 in the opening 121a, and the air of the plug-in unit 100 is absorbed (push) in the opening 122a. Accordingly, as indicated by thick arrows in FIG. 2, air moves from a lower side toward an upper side inside the plug-in unit 100 in FIG. 2. However, the arrangement of the fans 131 and 132 and the movement direction of the air are not limited to this. For example, the directions (pull and push) of the fans 131 and 132 may be reversed, and thereby, the air moves from the upper side toward the lower side inside the plug-in unit 100 in FIG. 2.

The power supply connector 141, the communication connector 142, and the light emitting unit 143 are installed in the front surface of the plug-in unit 100, and are connected to a circuit mounted on the board 110. The power supply connector 141 is a connector to which a power cable for supplying power to the board 110 of the plug-in unit 100 may be connected. The communication connector 142 is a communication connector to which a communication interface such as Ethernet is connected. The communication connector 142 corresponds to Ethernet such as 100 BASE-TX or 100 BASE-FX. Ethernet is a registered trademark. The light emitting unit 143 is a light emitting unit such as an LED that notifies a user of, for example, an operation state of the board 110. LED is an abbreviation for light emitting diode.

The back board connectors 151 to 153 are installed on a rear surface (right side in FIG. 2) of the plug-in unit 100, and are connected to a circuit mounted on the board 110. When the plug-in unit 100 is stored in the shelf-type transmission device, the back board connectors 151 to 153 are connected to a back board of the shelf-type transmission device.

The high-heat generating components 161 to 164 are heat generating elements mounted on the board 110. For example, the high-heat generating components 161 to 164 include each of circuits that realizes a function of the plug-in unit 100 such as signal transmission. In the example illustrated in FIG. 2, the four high-heat generating components 161 to 164 are mounted on the board 110, however, the number and an arrangement of the high-heat generating components are not limited to this.

The rectifying plate 170 is installed in the vicinity of the fan 132, rectifies the air taken in from the opening 122a by the fan 132, and sends the rectified air to the high-heat generating components 161 to 164. Thereby, it is possible to more efficiently supply an airflow to the high-heat generating components 161 to 164 and to improve cooling efficiency of the high-heat generating components 161 to 164.

For example, in the plug-in unit 100, since there is a turbulent flow on an air absorption side (push) and there is a laminar flow on the air discharge side (pull), wind blows more strongly on the air absorption side than on the air discharge side. A heat transfer rate is high on the air absorption side that is upwind, and the heat transfer rate decreases as it goes downwind. Thus, by installing the rectifying plate 170 at a position closer to the fan 132 on the air absorption side than the fan 131 on the air discharge side, cooling efficiency of the high-heat generating components 161 to 164 may be improved.

As illustrated in FIGS. 1 and 2, by installing the fans 131 and 132 in the plug-in unit 100, the cooling efficiency inside the plug-in unit 100 may be improved without adding a cooling device such as a fan to the shelf-type transmission device.

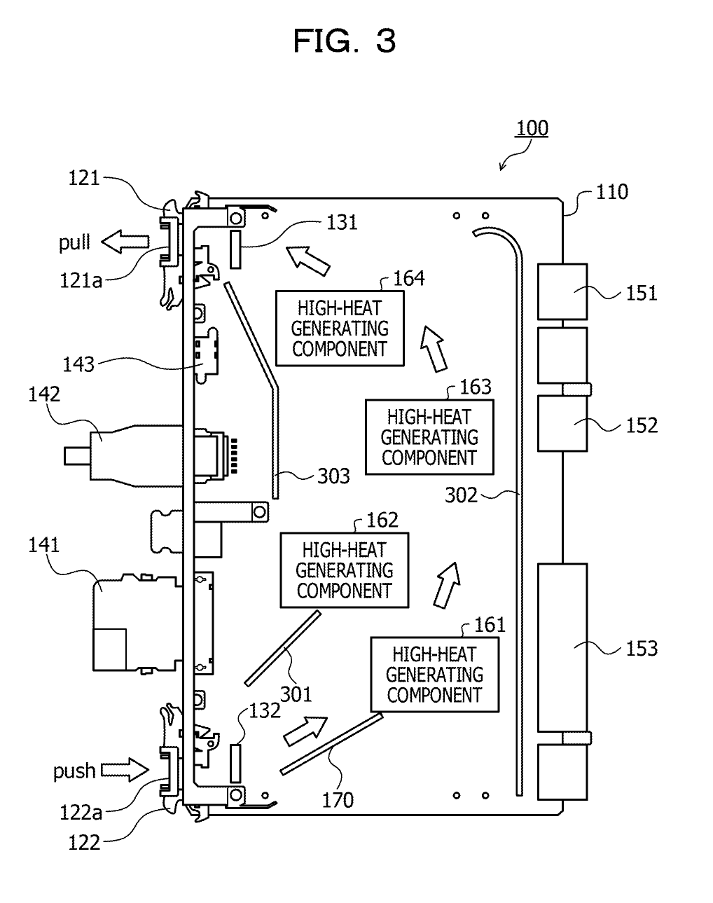

FIG. 3 is a top view illustrating another example of the plug-in unit of the transmission device according to Embodiment 1. In FIG. 3, portions which are similar to those illustrated in FIG. 2 are denoted by the same reference symbols and description thereof will be omitted. As illustrated in FIG. 3, the plug-in unit 100 may include rectifying plates 301 to 303 in addition to the configuration illustrated in FIG. 2. The rectifying plates 301 to 303 are arranged such that the air taken in from the opening 122a is discharged from the opening 121a by passing through each position of the high-heat generating components 161 to 164. Thereby, it is possible to more efficiently supply an airflow to the high-heat generating components 161 to 164 and to improve the cooling efficiency of the high-heat generating components 161 to 164.

As described above, according to Embodiment 1, the fans 131 and 132 are installed in the plug-in unit 100 mounted in a housing of the shelf-type transmission device or the like. Thereby, it is possible to improve the cooling efficiency of the plug-in unit 100 without adding a cooling device such as a fan to a housing side where it is difficult to secure a space.

The openings 121a and 122a are formed in the card levers 121 and 122 (operation tools) that receive an operation to take out the plug-in unit 100 from the housing, and the fans 131 and 132 move the air through the openings 121a and 122a. In Embodiment 1, by installing the fans 131 and 132 in the vicinity of the openings 121a and 122a, air may be moved through the openings 121a and 122a.

Thereby, it is possible to perform cooling through the openings 121a and 122a of the card levers 121 and 122 without installing a dedicated ventilation hole in the front surface of the plug-in unit 100. Therefore, it is possible to efficiently use a space on the front surface of the plug-in unit 100 in which various electronic components such as the power supply connector 141, the communication connector 142, the light emitting unit 143, and the like are installed.

By installing the fans 131 and 132 in the plug-in unit 100, the inside of the plug-in unit 100 may be more intensively cooled than a case where a cooling device such as a fan that cools the entire housing of the shelf-type transmission device or the like is added. Accordingly, it is possible to efficiently cool the inside of the plug-in unit 100.

A configuration in which the plug-in unit 100 is a processing device that executes processing relating to signal transmission is described, however, the processing executed by the plug-in unit 100 is not limited to processing relating to the signal transmission and may be various types of processing. The device that stores the plug-in unit 100 is not limited to the shelf-type transmission device and may be various electronic apparatuses that may mount a plurality of plug-in units including the plug-in unit 100.

### Embodiment 2

In Embodiment 2, portions different from those in Embodiment 1 will be described. In Embodiment 2, a configuration of the plug-in unit 100 including the fans 131 and 132 in the openings 121a and 122a of the card levers 121 and 122 will be described.

Plug-In Unit of Transmission Device According to Embodiment 2

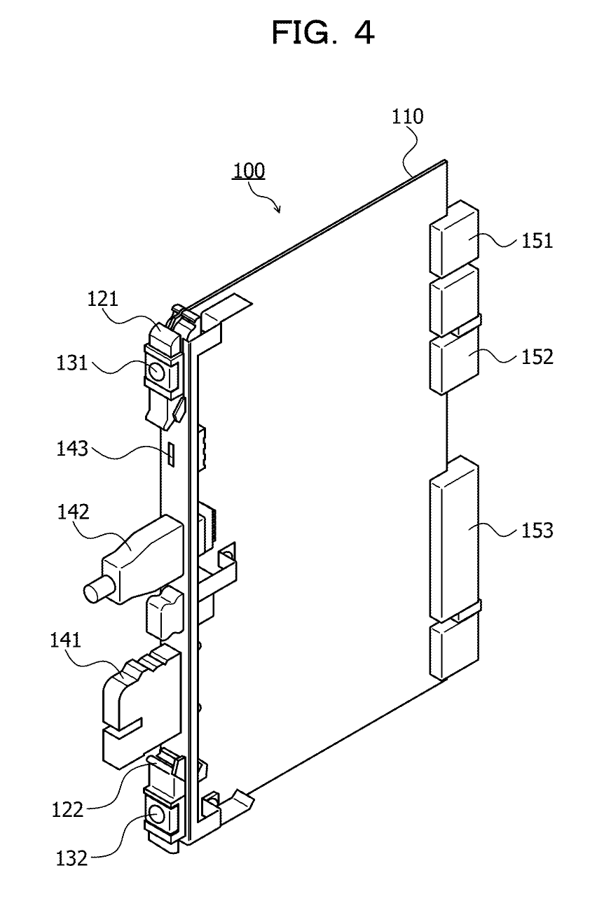

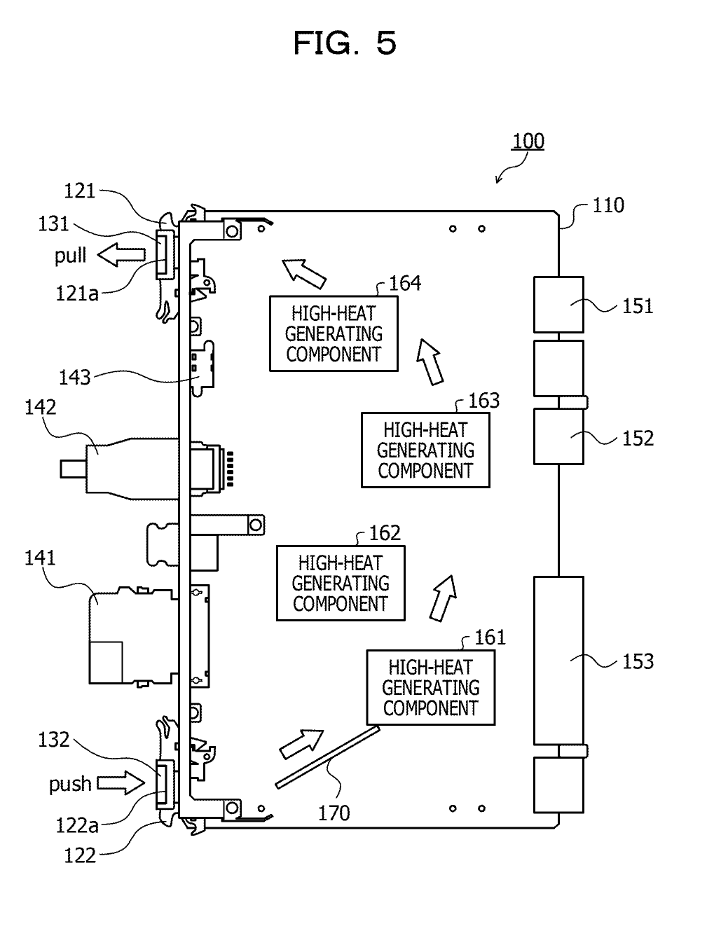

FIG. 4 is a perspective view illustrating an example of a plug-in unit of a transmission device according to Embodiment 2. FIG. 5 is a top view illustrating the example of the plug-in unit of the transmission device according to Embodiment 2. In FIGS. 4 and 5, portions which are similar to those illustrated in FIGS. 1 and 2 are denoted by the same reference symbols, and description thereof will be omitted. As illustrated in FIGS. 4 and 5, the plug-in unit 100 according to Embodiment 2 includes the fans 131 and 132 in the openings 121a and 122a of the card levers 121 and 122, respectively.

As described above, according to Embodiment 2, by installing the fans 131 and 132 in the openings 121a and 122a of the card levers 121 and 122, air may efficiently move through the openings 121a and 122a. Thereby, it is possible to improve cooling efficiency of the plug-in unit 100.

By providing the fans 131 and 132 on the card levers 121 and 122 installed on positions (front surface) where a user may operate, the hand of the user may easily reach the fans 131 and 132, and thus, replacement, cleaning, and the like of the fans 131 and 132 become easy. For example, even in a case where the plug-in unit 100 is attached to the shelf-type transmission device to be operated, replacement, cleaning, and the like of the fans 131 and 132 may be made. Thereby, for example, it is possible to perform replacement, cleaning, and the like, for the fans 131 and 132, while suppressing occurrence of communication troubles due to loss of signal in the plug-in unit 100.

It is possible to respectively install the fans 131 and 132 in the card levers 121 and 122 installed at both ends, in the longitudinal direction, of the front surface of the plug-in unit 100 and to perform air absorption and air discharge by using the fans 131 and 132, respectively. Thereby, it is possible to efficiently move the air inside the plug-in unit 100, and thus, cooling efficiency of the plug-in unit 100 may be improved.

### Embodiment 3

In Embodiment 3, portions different from those in Embodiment 1 and Embodiment 2 will be described. In Embodiment 3, a configuration of the plug-in unit 100 including a switch that causes power not to be supplied from the board 110 to the fans 131 and 132 in accordance with at least part of an operation on the card levers 121 and 122 will be described.

Fan According to Embodiment 3

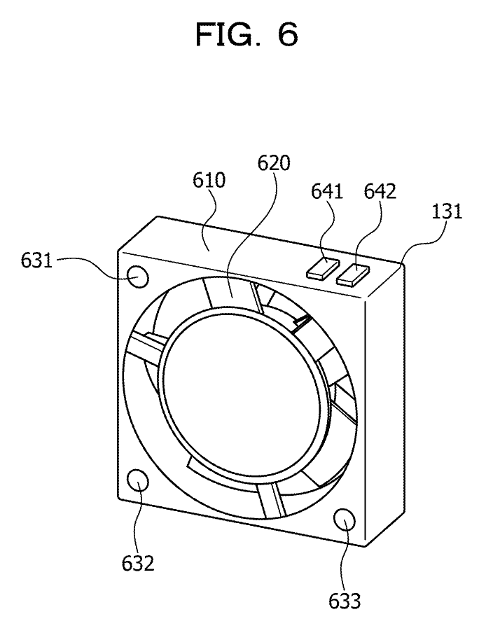

FIG. 6 is a perspective view illustrating an example of a fan according to Embodiment 3. Although a configuration of the fan 131 will be described, a configuration of the fan 132 is similar to the configuration of the fan 131. As illustrated in FIG. 6, the fan 131 according to Embodiment 3 includes a housing 610, a propeller unit 620, boss holes 631 to 633, and power supply contacts 641 and 642.

The housing 610 stores the propeller unit 620 and has a shape that fits into the opening 121a of the card lever 121. As an example, an inner peripheral portion of the opening 121a is a rectangle of approximately 20 mm×20 mm, and an outer peripheral portion of the housing 610 is also a rectangle of approximately 20 mm×20 mm.

The propeller unit 620 rotates in the housing 610, thereby moving the air. For example, the propeller unit 620 includes a motor electrically connected to the power supply contacts 641 and 642, and is rotated by power supplied via the power supply contacts 641 and 642.

The boss holes 631 to 633 are used for fixing the housing 610 to the card lever 121. In the example illustrated in FIG. 6, the boss holes 631 to 633 are each installed at three corners of the housing 610. The power supply contacts 641 and 642 are electrodes electrically connected to the motor of the propeller unit 620 and exposed to the outside of the housing 610.

Front Surface of Card Lever According to Embodiment 3

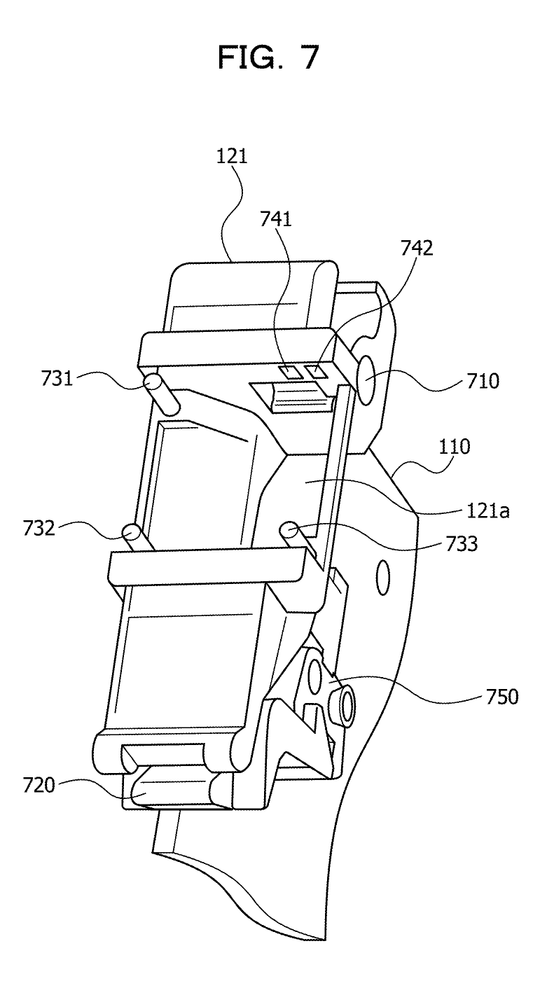

FIG. 7 is a perspective view illustrating an example of a front surface of a card lever according to Embodiment 3. Although a configuration of the card lever 121 will be described, a configuration of the card lever 122 is similar to the configuration of the card lever 121. As illustrated in FIG. 7, the card lever 121 according to Embodiment 3 includes a fulcrum 710, a handle 720, bosses 731 to 733, power supply contacts 741 and 742, and a latch 750.

The fulcrum 710 is fixed to the board 110. The card lever 121 rotates around the fulcrum 710 with respect to the board 110. The handle 720 is a portion that a user holds when operating the card lever 121. In the example illustrated in FIG. 7, the card lever 121 is in a closed state. In this state, when the user holds the handle 720 and pulls the handle 720, the card lever 121 may be opened (see, for example, FIGS. 12 and 13).

The bosses 731 to 733 are projections that fit into the boss holes 631 to 633 illustrated in FIG. 6 respectively when the fan 131 illustrated in FIG. 6 is fit into the opening 121a. The power supply contacts 741 and 742 are electrodes which contact the power supply contacts 641 and 642 illustrated in FIG. 6 respectively when the fan 131 illustrated in FIG. 6 is fit into the opening 121a.

The latch 750 is fixed to the board 110, and when a user closes the card lever 121, the card lever 121 is hooked and the card lever 121 is fixed in a closed state. The latch 750 releases the card lever 121 in a case where the user holds the handle 720 with a certain degree of force, and cancels a state where the card lever 121 is closed.

Front Surface in State Where Fan is Attached to Card Lever According to Embodiment 3

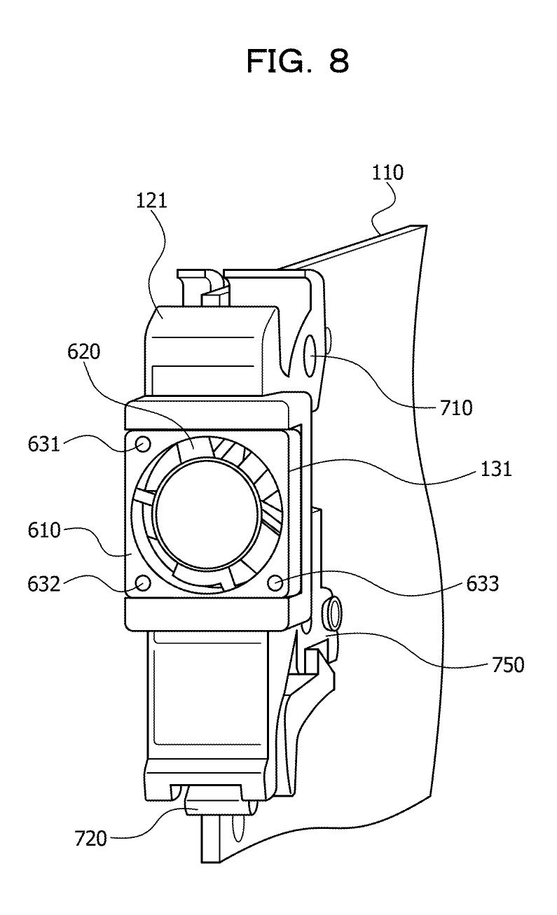

FIG. 8 is a perspective view illustrating an example of a front surface in a state where the fan is attached to the card lever according to Embodiment 3. In FIG. 8, portions which are similar to those illustrated in FIGS. 6 and 7 are denoted by the same reference symbols, and description thereof will be omitted. As illustrated in FIG. 8, if the fan 131 is fit into the opening 121a of the card lever 121, the bosses 731 to 733 are fit into the boss holes 631 to 633, and the fan 131 is fixed to the opening 121a. As the fan 131 fits into the opening 121a, the power supply contacts 641 and 642 of the fan 131 come into contact with the power supply contacts 741 and 742 of the card lever 121, respectively.

As illustrated in FIGS. 6 and 7, the plug-in unit 100 according to Embodiment 3 has a configuration in which the power supply contacts 641 and 642 are installed outside the fan 131 and the power supply contacts 741 and 742 are installed inside the opening 121a. Thereby, as illustrated in FIG. 8, by fitting the fan 131 into the opening 121a, the power supply contacts 641 and 642 and the power supply contacts 741 and 742 come into contact with each other. Thereby, wiring for supplying power to the fan 131 is not performed separately from the operation of fitting the fan 131 into the opening 121a, and thus, the operation of attaching the fan 131 is easily performed.

By removing the fan 131 from the opening 121a, the power supply contacts 641 and 642 and the power supply contacts 741 and 742 are separated from each other. Thereby, an operation of cutting a power supply wire of the fan 131 is not performed separately from the operation of removing the fan 131 from the opening 121a, and thus, the operation of removing the fan 131 is easily performed.

Rear Surface of Card Lever According to Embodiment 3

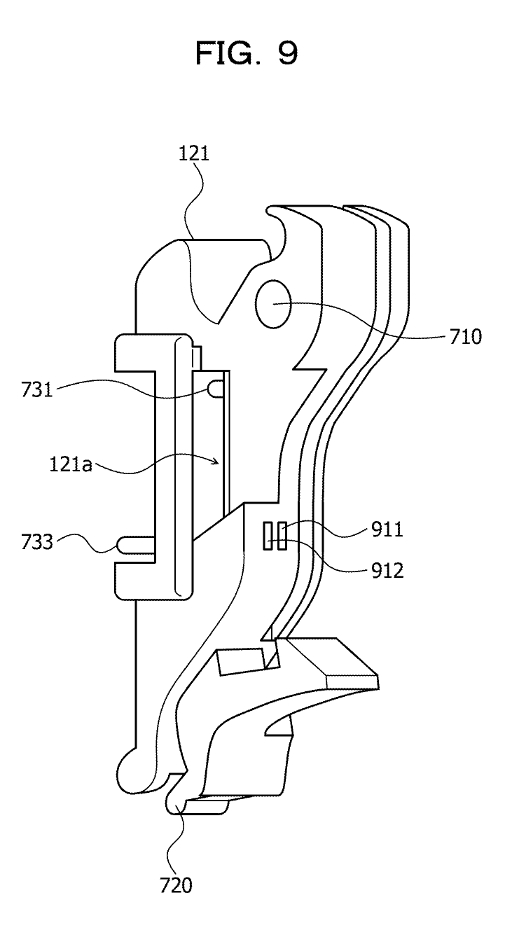

FIG. 9 is a perspective view illustrating an example of a rear surface of the card lever according to Embodiment 3. In FIG. 9, portions which are similar to those illustrated in FIG. 7 are denoted by the same reference symbols, and description thereof will be omitted. As illustrated in FIG. 9, power supply contacts 911 and 912 are installed on the rear surface of the card lever 121 according to Embodiment 3. The power supply contacts 911 and 912 are electrically connected to the power supply contacts 741 and 742, respectively, illustrated in FIG. 7 via, for example, conductors buried in the card lever 121.

Rear Surface in State Where Fan is Attached to Card Lever According to Embodiment 3

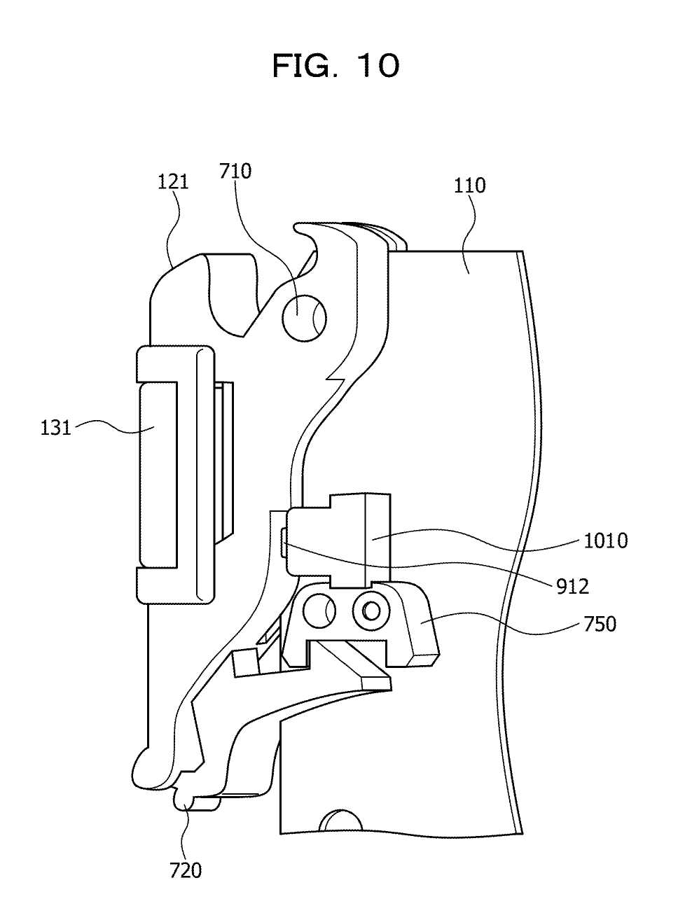

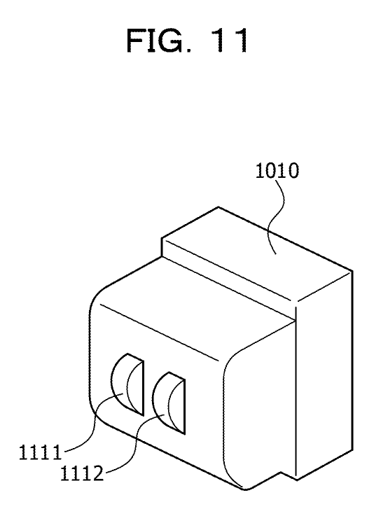

FIG. 10 is a perspective view illustrating an example of a rear surface in a state where the fan is attached to the card lever according to Embodiment 3. FIG. 11 is a perspective view illustrating an example of a power supply connector according to Embodiment 3. In FIG. 10, portions which are similar to those illustrated in FIGS. 8 and 9 are denoted by the same reference symbols, and description thereof will be omitted. A power supply connector 1010 illustrated in FIG. 10 is installed on the board 110, and supplies power (voltage) output from the board 110 to the card lever 121.

For example, as illustrated in FIG. 11, the power supply connector 1010 includes power supply contacts 1111 and 1112. The power supply contacts 1111 and 1112 are connected to a circuit of the board 110 via, for example, a conductor buried in the power supply connector 1010.

FIG. 10 illustrates the card lever 121 in a state where the fan 131 is attached thereto. As illustrated in FIG. 10, if the card lever 121 is closed, the power supply contacts 911 and 912 of the card lever 121 come into contact with the power supply contacts 1111 and 1112 of the power supply connector 1010, respectively. Thereby, power from the circuit of the board 110 is supplied to the fan 131 via the power supply connector 1010 and the card lever 121, and then the fan 131 operates.

As such, the power supply contacts 911 and 912 of the card lever 121 and the power supply contacts 1111 and 1112 of the power supply connector 1010 become switches that cause the power not to be supplied to the fans 131 and 132 according to an operation of the card lever 121.

State When Card Lever According to Embodiment 3 is Opened

FIG. 12 is a diagram illustrating an example of a situation of a front surface when the card lever according to Embodiment 3 is opened. FIG. 13 is a diagram illustrating an example of a situation of a rear surface when the card lever according to Embodiment 3 is opened. In FIGS. 12 and 13, portions which are similar to those illustrated in FIGS. 8 and 10 are denoted by the same reference symbols, and description thereof will be omitted. As illustrated in FIGS. 12 and 13, when the card lever 121 is opened, a state of the card lever 121 changes in the order of a card lever state 1201, a card lever state 1202, a card lever state 1203, and a card lever state 1204.

The card lever state 1201 is a state illustrated in FIGS. 8 and 10, for example, a state where the card lever 121 is closed and fixed by the latch 750. In the card lever state 1201, the plug-in unit 100 is fixed to the shelf-type transmission device, and thereby, the plug-in unit 100 may not be taken out from the shelf-type transmission device.

In the card lever state 1201, if a user pulls on the handle 720, the card lever 121 is disengaged from the latch 750, the card lever 121 rotates around the fulcrum 710, and the card lever state 1202 is obtained. Furthermore, if the user pulls on the handle 720, the card lever 121 rotates, and the card lever state 1203 is obtained. Furthermore, if the user pulls on the handle 720, the card lever 121 rotates, and the card lever state 1204 is obtained.

In the card lever state 1204, the plug-in unit 100 is released from the shelf-type transmission device, and if the user pulls on the plug-in unit 100 in a direction toward the user, the plug-in unit 100 may be taken out from the shelf-type transmission device. The direction toward the user is a left direction in FIGS. 12 and 13.

In the card lever state 1201, as described above, the power output from the circuit of the board 110 is supplied to the fan 131 via the power supply connector 1010 and the card lever 121, and the fan 131 rotates. Meanwhile, in the card lever state 1202, the card lever state 1203, and the card lever state 1204, the power supply contacts 911 and 912 of the card lever 121 are separated from the power supply contacts 1111 and 1112 of the power supply connector 1010. Thus, the power output from the circuit on the board 110 is not supplied to the fan 131, and the fan 131 does not rotate.

Although the situation at the time of opening the card lever 121 is described, when the card lever 121 is closed, a state of the card lever 121 is changed in the order of the card lever state 1204, the card lever state 1203, the card lever state 1202, and the card lever state 1201. Returning to the card lever state 1201 in which the card lever 121 is closed, the power output from the circuit on the board 110 is supplied to the fan 131, and the fan 131 rotates.

As illustrated in FIGS. 9 to 13, the power supply contacts 911 and 912 and the power supply contacts 1111 and 1112 are installed on the card lever 121 and the power supply connector 1010, respectively, and by operating the card lever 121, the fan 131 may be turned on/off.

As such, the plug-in unit 100 according to Embodiment 3 includes a switch that causes power not to be supplied from the board 110 to the fan 131, according to at least part of the operation on the card lever 121. This switch is realized by, for example, power supply contacts 911, 912, 1111, and 1112.

Thereby, for example, in a state where the plug-in unit 100 is attached to the shelf-type transmission device and is in operation, the fan 131 may be stopped by operating the card lever 121, and replacement, cleaning, and the like of the fan 131 may be performed safely. As compared with a configuration in which an operation tool for stopping the fan 131 is installed separately from the card lever 121, a function of stopping the fan 131 may be realized with a simple configuration.

The power supply contacts 741 and 742, which come into contact with the power supply contacts 641 and 642 of the fan 131 and supply the power to the fan 131 if the fan 131 is attached to the opening 121a, are installed inside the opening 121a of the card lever 121. Thereby, it becomes easy to attach and remove the fan 131. This configuration is not limited to Embodiment 3 and may also be applied to, for example, Embodiment 2 described above. In this case, for example, the power supply contacts 741 and 742 of the card lever 121 are electrically connected to a power supply portion of the board 110 by a copper wire or the like, and the power from the board 110 is supplied to the power supply contacts 741 and 742 regardless of the open/closed state of the card lever 121.

The configurations of the card lever 121 and the fan 131 are described, however, the configurations of the card lever 122 and the fan 132 may also be similar to the configurations of the card lever 121 and the fan 131.

Shelf-type Transmission Device Capable of Storing Plug-In Unit According to Each Embodiment

FIG. 14 is a perspective view illustrating an example of the shelf-type transmission device capable of storing the plug-in unit according to each embodiment. The plug-in unit 100 according to each embodiment described above may be stored in, for example, a shelf-type transmission device 1400 illustrated in FIG. 14. The shelf-type transmission device 1400 includes, for example, a housing 1410, meshes 1421 to 1423, and a back board 1430.

The housing 1410 is capable of storing the plurality of plug-in units 100. The meshes 1421 to 1423 for ventilation are installed on an upper surface of the housing 1410 (surface on an upper side in FIG. 14). The back board 1430 is a board for controlling the plug-in unit 100 stored in the shelf-type transmission device 1400 and for communicating between the plug-in units 100 stored in the shelf-type transmission device 1400. If the plug-in unit 100 is stored in the shelf-type transmission device 1400, the above-described back board connectors 151 to 153 are connected to the back board 1430. For example, the back board 1430 is a back wiring board (BWB).

The shelf-type transmission device 1400 illustrated in FIG. 14 is a natural air-cooling device that does not include a cooling device such as a fan in the housing 1410. However, the shelf-type transmission device 1400 is not limited to the natural air-cooling device, and may be a forced air-cooling device including a cooling device such as a fan in the housing 1410.

Each of the plug-in units 100 (#1 to #4) illustrated in FIG. 14 is, for example, the plug-in unit 100 according to Embodiment 2 or Embodiment 3 described above. The shelf-type transmission device 1400 may store, for example, the plug-in unit 100 according to Embodiment 1 described above. The shelf-type transmission device 1400 may be able to store the plug-in units 100 according to the respective embodiments described above in a mixed manner. The shelf-type transmission device 1400 may be able to store at least one of the plug-in units 100 according to the respective embodiments described above and another plug-in unit not including a fan in a mixed manner.

As described above, according to the transmission device and the electronic apparatus, cooling efficiency of the plug-in unit may be improved.

For example, in a recent communication device, as transmission capacity increases, a transmission signal of a package increases in speed. Since power consumption also increases due to a function addition (enhancement) to the current package or the like, forced air cooling or the like is performed to cool the package.

For example, in a case where power consumption of each package stored in a shelf is small, a natural air-cooling device may be used which cools the respective packages by absorbing the air from a lower stage of the shelf and discharging the air from an upper stage in an airflow in a device installation environment. Meanwhile, in the current natural air-cooling device, in a case where a high-heat generating package is stored according to enhancement, an airflow in the environment where the device is installed may not satisfy an allowable temperature of a component mounted in the package.

Accordingly, forced air cooling is performed by a fan or the like. However, in a case where there is no space to add a fan or the like, there are problems that reconsideration, redesign, and the like are performed on a structure of a device, and a large cost is incurred. For example, in order to mount a fan on an upper portion of the natural air-cooling device, a structure of a housing of the natural air-cooling device is changed.

In contrast, according to the respective embodiments described above, a fan is included in the plug-in unit 100 (package) itself, and thereby, even without adding a cooling device such as a fan to the housing, it is possible to improve the cooling efficiency of the inside of the plug-in unit 100. Accordingly, it is desirable to improve the cooling efficiency of the inside of the plug-in unit 100 without providing a forced air-cooling device obtained by installing a fan in a housing of the natural air-cooling device, or without adding a fan to the housing of the forced air-cooling device. For example, it is possible to perform air cooling for a heat generating elements (for example, the high-heat generating components 161 to 164) of the plug-in unit 100 while suppressing an increase in cost.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A transmission device comprising:
a housing; and
a plurality of plug-in assemblies mounted in the housing, wherein
each of the plug-in assembly that executes signal transmission and includes a board, heat generating parts mounted over the board and a fan that cools the heat generating parts.

2. The transmission device according to claim 1, wherein
the plug-in assembly that includes an operation tool for taking out the plug-in assembly from the housing and an opening for cooling the heat generating parts.

3. The transmission device according to claim 2, wherein
the fan is arranged near the opening and cools the heat generating parts by moving air through the opening.

4. The transmission device according to claim 2, wherein
the fan is installed in the opening and cools the heat generating parts by moving air through the opening.

5. The transmission device according to claim 4, wherein
the fan operates by power that is supplied from the board, and
a switch that causes the power to be not supplied from the board to the fan, according to at least part of the operation on the operation tool, is installed.

6. The transmission device according to claim 5,
wherein the switch causes the power to be supplied from the board to the fan, according to at least part of an operation on the operation tool for attaching the plug-in assembly including the fan to the housing, in a state where the power is not supplied from the board to the fan.

7. The transmission device according to claim 4,
wherein the plug-in assembly is a card type plug-in assembly,
the operation tool is installed at each end, in a longitudinal direction, of one surface of the plug-in assembly including the fan, and
the fan is installed in the opening of each of the operation tools that is installed at the both ends.

8. The transmission device according to claim 7,
wherein the fan includes
a fan that is installed in the opening of the operation tool which is installed at a first end of the both ends and absorbs air into the plug-in assembly including the fan, and
another fan that is installed in the opening of the operation tool which is installed at a second end of the both ends and discharges the air from the plug-in assembly including the fan.

9. The transmission device according to claim 4,
wherein the fan operates by the power that is supplied from the board, and
the operation tool includes an electrode which comes into contact with an electrode of the fan and supplies the power to the fan when the fan is attached to the opening.

10. The transmission device according to claim 1, further comprising:
a rectifying plate that is installed on the board, rectifies air which is moved by the fan, and sends the rectified air to the heat generating parts.

11. The transmission device according to claim 10,
wherein the fan includes
a fan that absorbs air in the plug-in assembly including the fan, and
another fan that discharges the air in the plug-in assembly including the fan, and
the rectifying plate is installed at a position closer to the fan that absorbs the air than the fan that discharges the air.

12. An electronic apparatus comprising:
a housing; and
a plurality of plug-in assemblies mounted in the housing, wherein
each of the plug-in assembly that executes signal transmission and includes a board, heat generating parts mounted over the board and a fan that cools the heat generating parts.
